(19) United States
(12) Patent Application Publication
(10) Pub. No.: US 2008/0272471 A1
(43) Pub. Date: Nov. 6, 2008

(54) ELECTRO-OPTICAL DEVICE AND ELECTRONIC APPARATUS

(75) Inventors: Hiroyuki ONODERA, Matsumoto (JP); Yasuhito ARUGA, Matsumoto (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/145,800

(22) Filed: Jun. 25, 2008

Related U.S. Application Data
(62) Division of application No. 11/225,647, filed on Sep. 13, 2005.

(30) Foreign Application Priority Data
Sep. 30, 2004 (JP) 2004-288681

(51) Int. Cl. H01L 23/495

(52) U.S. Cl. 257/668; 257/E23.031

(57) ABSTRACT

An electro-optical device includes an electro-optical panel having a substrate; a plurality of input terminals that are arranged in a first direction on the substrate; and a semiconductor device provided with a plurality of input bumps electrically connected to the input terminals through conductive organic members. The input terminals connected to the input bumps that are positioned substantially at the center of the semiconductor device in the first direction have allowable connection resistance values smaller than those of the other input terminals.

### CROSS-REFERENCE TO RELATED APPLICATIONS

This application is a divisional of U.S. patent application Ser. No. 11/225,647 filed on Sep. 13, 2005. This application claims the benefit of Japanese Patent Application No. 2004-288681 filed Sep. 30, 2004. The disclosures of the above applications are incorporated herein by reference.

### BACKGROUND OF THE INVENTION

1. Technical Field

The present invention relates to an electro-optical device having a semiconductor device mounted on a substrate thereof through a conductive organic member, and to an electronic apparatus.

2. Related Art

An electro-optical device, such as a liquid crystal device fabricated using a COG (chip-on-glass) method, includes a liquid crystal panel in which a liquid crystal layer is interposed between a pair of glass substrates, a pair of polarizing plates opposite to each other with the liquid crystal panel interposed therebetween, a semiconductor device mounted on the glass substrate of the liquid crystal panel by a thermal pressing method, a flexible wiring substrate electrically connected to the substrate of the liquid crystal panel, and a circuit board electrically connected to the flexible wiring substrate. In addition, terminals on the substrate of the liquid crystal panel are electrically connected to bumps of the semiconductor device through an ACF (anisotropic conductive film) serving as a conductive organic member. Further, mounting components constituting, for example, a control circuit, a power supply control circuit, and a voltage boosting circuit are mounted on the circuit board by soldering (see Japanese Unexamined Patent Application Publication No. 2001-156418 (paragraph Nos. [0036] to [0045]).

In recent years, in order to reduce the size of liquid crystal devices, some components, such as a control circuit, a power supply control circuit, and a voltage boosting circuit, have been incorporated into a semiconductor device mounted on the glass substrate of the liquid crystal panel.

However, in liquid crystal devices fabricated using the COG method, since the glass substrate and the semiconductor device have different thermal expansion coefficients, the semiconductor device is mounted on the glass substrate in a warped state in a thermal pressing process. Therefore, the ACF positioned outside a central portion of the semiconductor device becomes loose over time, which causes high connection resistance between the bumps of the semiconductor device and the terminals of the liquid crystal panel at the edge of the semiconductor device. As a result, display characteristics of the liquid crystal panel are deteriorated.

### SUMMARY

An advantage of the invention is that it provides an electro-optical device and an electronic apparatus capable of preventing the deterioration of display characteristics even when connection resistance between terminals and bumps of a semiconductor device varies over time.

According to an aspect of the invention, an electro-optical device includes an electro-optical panel having a substrate; a plurality of input terminals that are arranged in a first direction on the substrate; and a semiconductor device provided with a plurality of input bumps electrically connected to the input terminals through a conductive organic member. In the electro-optical device, the input terminals connected to the input bumps that are positioned substantially at the center of the semiconductor device in the first direction have allowable connection resistance values smaller than those of the other input terminals.

According to this structure, the input terminals connected to the input bumps that are positioned substantially at the center of the semiconductor device in the first direction have the allowable connection resistance values smaller than those of the other input terminals. Therefore, even when the conductive organic member between the input bumps and the input terminals becomes loose over time, a variation in connection resistance between the input bumps and the input terminals at the center of the semiconductor device is smaller than that at both sides of the semiconductor device, which makes it possible to achieve an electro-optical device having stable operational characteristics. That is, when the substrate and the semiconductor device have different thermal expansion coefficients, the semiconductor device is mounted on the substrate in a warped state in the thermal pressing process. Then, the conductive organic member becomes loose at the edge of the semiconductor device in the first direction over time, which causes high connection resistance between the input terminals and the input bumps at the edge of the semiconductor device. However, in the invention, the input terminals are arranged to be electrically connected to the input bumps that are positioned at the center of the semiconductor device where the connection resistance is hardly varied even when the conductive organic member becomes loose over time. Therefore, even when the conductive organic member becomes loose over time, the connection resistance between the input bumps and the input terminals corresponding thereto is hardly varied at the center of the semiconductor device. Thus, it is possible to prevent the deterioration of display characteristics of an electro-optical device due to a variation in connection resistance over time.

Further, in the above-mentioned structure, it is preferable that at least one of a power supply terminal, a power supply control terminal, and a ground terminal required to have a small connection resistance value be connected to the input bump that is positioned substantially at the center of the semiconductor device in the first direction.

According to this structure, at least one of the power supply terminal, the power supply control terminal, and the ground terminal required to have a small connection resistance value is arranged as an input terminal electrically connected to the input bump that is positioned at the center of the semiconductor device where the connection resistance is hardly varied even when the conductive organic member becomes loose over time. In this way, even when the conductive organic member becomes loose over time, the connection resistance between the input bumps and the input terminals corresponding thereto is hardly varied at the center of the semiconductor device. Thus, it is possible to prevent the deterioration of display characteristics of an electro-optical device due to a variation in connection resistance over time.

Further, in the above-mentioned structure, it is preferable that the semiconductor device and the substrate have different thermal expansion coefficients.

According to this structure, when the substrate and the semiconductor device have different thermal expansion coefficients, the semiconductor device is mounted on the substrate in a warped state in the thermal pressing process. Then, the conductive organic member becomes loose at the edge of the semiconductor device in the first direction over time, which causes high connection resistance between the input terminals and the input bumps at the edge of the semiconductor device. However, in the invention, at least one of the power supply terminal, the power supply control terminal, and the ground terminal required to have a small connection resistance value is arranged as an input terminal electrically connected to the input bump that is positioned at the center of the semiconductor device where the connection resistance is hardly varied even when the conductive organic member becomes loose over time. In this way, even when the conductive organic member becomes loose over time, the connection resistance between the input bumps and the input terminals corresponding thereto is hardly varied at the center of the semiconductor device. Thus, it is possible to prevent the deterioration of display characteristics of an electro-optical device due to a variation in connection resistance over time.

Furthermore, in the above-mentioned structure, it is preferable that the plurality of input bumps be arranged such that the maximum allowable connection resistance values between the input bumps and the input terminals decrease from an outer side toward an inner side in the first direction.

According to this structure, since the input bumps are arranged such that the maximum allowable connection resistance values between the input bumps and the input terminals decrease from the outer side toward the inner side, it is possible to reliably prevent the deterioration of display characteristics of an electro-optical device due to a variation in connection resistance over time.

Moreover, according to another aspect of the invention, an electronic apparatus includes the above-mentioned electro-optical device.

This structure prevents the deterioration of display characteristics of an electro-optical device due to a variation in connection resistance between the input terminals and the input bumps of the semiconductor device over time. Therefore, it is possible to achieve an electronic apparatus including a display having stable display characteristics.

### BRIEF DESCRIPTION OF THE DRAWINGS

The invention will be described with reference to the accompanying drawings, wherein like numbers reference like elements, and wherein:

FIG. 1 is a block diagram schematically illustrating the electrical structure of a liquid crystal device according to a first embodiment of the invention;

FIG. 2 is a perspective view schematically illustrating the liquid crystal device according to the first embodiment;

FIG. 3 is a schematic diagram illustrating the relationship between terminals and bumps of a driving IC according to the first embodiment;

FIG. 4 is an explanatory diagram of the terminals connected to the bumps of the driving IC according to the first embodiment (part 1);

FIG. 5 is an explanatory diagram of the terminals connected to the bumps of the driving IC according to the first embodiment (part 2);

FIG. 6 is an explanatory diagram of the terminals connected to the bumps of the driving IC according to the first embodiment (part 3);

FIG. 7 is a cross-sectional view illustrating the mounting state of the driving IC;

FIG. 8 is a schematic diagram illustrating the relationship between terminals and bumps of a driving IC according to a second embodiment of the invention;

FIG. 9 is an explanatory diagram of the terminals connected to the bumps of the driving IC according to the second embodiment;

FIG. 10 is an explanatory diagram of terminals connected to bumps of a driving IC according to a third embodiment; and

FIG. 11 is a diagram schematically illustrating the overall structure of a display control system of an electronic apparatus according to the invention.

### DESCRIPTION OF THE EMBODIMENTS

Hereinafter, preferred embodiments of the invention will be described with reference to the accompanying drawings. In the following description of the embodiment, a liquid crystal display device is exemplified as an electro-optical device. Specifically, an active matrix liquid crystal device using TFD elements of a COG (chip-on-glass) type will be described as an example, but the invention is not limited thereto. In addition, in each drawing, the scale of each layer or member is adjusted in order to have a recognizable size.

### Electro-Optical Device

### First Embodiment

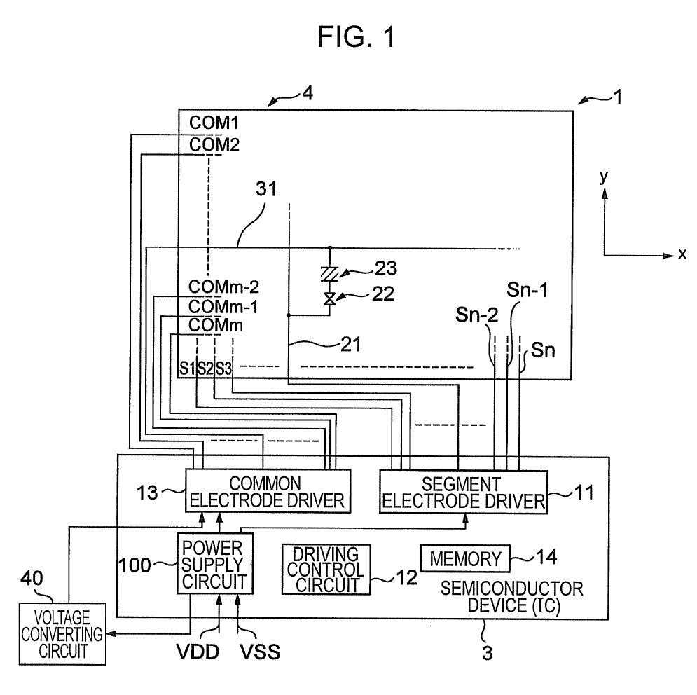

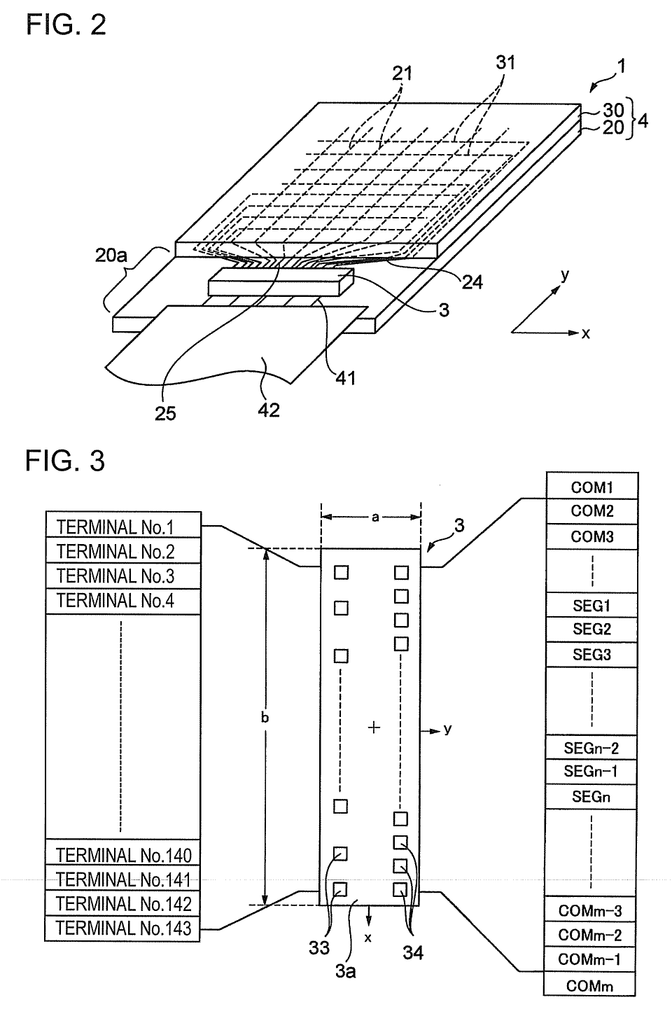

FIG. 1 is a block diagram schematically illustrating the electrical structure of a liquid crystal device, serving as an electro-optical device according to a first embodiment of the invention. FIG. 2 is a perspective view schematically illustrating the liquid crystal device.

As shown in FIGS. 1 and 2, a liquid crystal device 1 includes a liquid crystal panel 4 serving as an electro-optical panel, a pair of polarizing plates (not shown) which are provided opposite to each other with the liquid crystal panel 4 interposed therebetween, a flexible wiring substrate 42 that is electrically connected to the liquid crystal panel 4, a driving IC 3, serving as a semiconductor device, that is mounted on the liquid crystal panel 4, and a circuit board (not shown) that is electrically connected to the flexible wiring substrate 42.

The liquid crystal panel 4 has a first glass substrate 20 and a second glass substrate 30 composed of a pair of rectangular glass members which are bonded to each other by a substantially rectangular sealing material (not shown). Twisted nematic (TN) liquid crystal 23 in which liquid crystal molecules are twisted at an angle of, for example, 90°, serving as an electro-optical material, is held in a region surrounded by the first glass substrate 20, the second glass substrate 30, and the sealing material.

A plurality of segment electrodes (n segment electrodes) 21 are provided on the first glass substrate 20 so as to extend in the y direction, and a plurality of common electrodes (m common electrodes) 31 are provided on the second glass substrate 30 so as to extend in the x direction. In addition, thin film diodes (hereinafter, referred to as TFDs) 22, which are an example of two-terminal switching elements, and pixel electrodes (not shown) are provided to respectively correspond to intersections of the segment electrodes 21 and the common electrodes 31 on the first glass substrate 20.

The first glass substrate 20 has a projecting portion 20a protruding from the edge of the second glass substrate 30, and the driving IC 3, serving as a semiconductor device, is mounted on the projecting portion 20a. The projecting portion 20a is provided with input terminals 41 that are electrically connected to input bumps (reference numeral 33; which will be described later) of the driving IC 3 through an anisotropic conductive film (ACF; reference numeral 43; which will be described later), segment electrode output terminals 25 that are electrically connected to output bumps (reference numeral 34, which will be described later) of the driving IC 3 through the ACF, and common electrode output terminals 24. The input terminals 41 are provided in an x direction, which is a first direction. The segment electrode output terminals 25 extend from the segment electrodes 21, and the common electrode output terminals 24 are electrically connected to the common electrodes 31 through conductive materials (not shown) contained in the sealing material.

The driving IC 3 includes a segment electrode driver 11, a common electrode driver 13, a driving control circuit 12, a memory (display data RAM) 14, and a power supply circuit 100.

The memory (display data RAM) 14 stores display data of images to be displayed on the liquid crystal panel 4. The segment electrode driver 11 drives the segment electrodes 21 on the basis of the display data stored in the memory 14. The common electrode driver 13 drives the common electrodes 31.

The power supply circuit 100 generates various potentials using a ground power source potential VSS and a system power source potential VDD supplied from the outside, and supplies them to each unit of the liquid crystal device 1. More specifically, the power supply circuit 100 supplies a potential required for driving the common electrodes 31 to the common electrode driver 13, and supplies a potential required for driving the segment electrodes 21 to the segment electrode driver 11. In addition, the power supply circuit 100 supplies predetermined potentials to the driving control circuit 12 and the memory 14.

In this embodiment, out of the potentials required for driving the common electrodes 31, a positive potential with respect to the ground power source potential VSS is supplied to the common electrode driver 13. Therefore, the liquid crystal device 1 of this embodiment further includes a voltage converting circuit 40. The voltage converting circuit 40 generates a negative potential with respective to the ground power source potential VSS, using the potential generated from the power supply circuit 100, and supplies it to the common electrode driver 13.

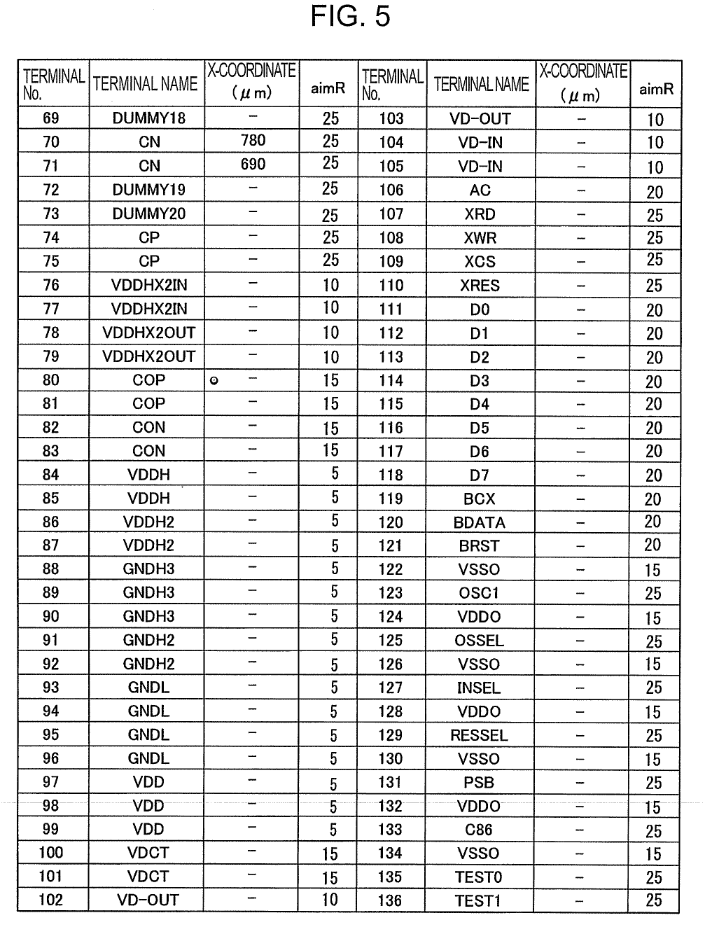

Next, the driving IC 3 will be described with reference to FIGS. 3 to 6.

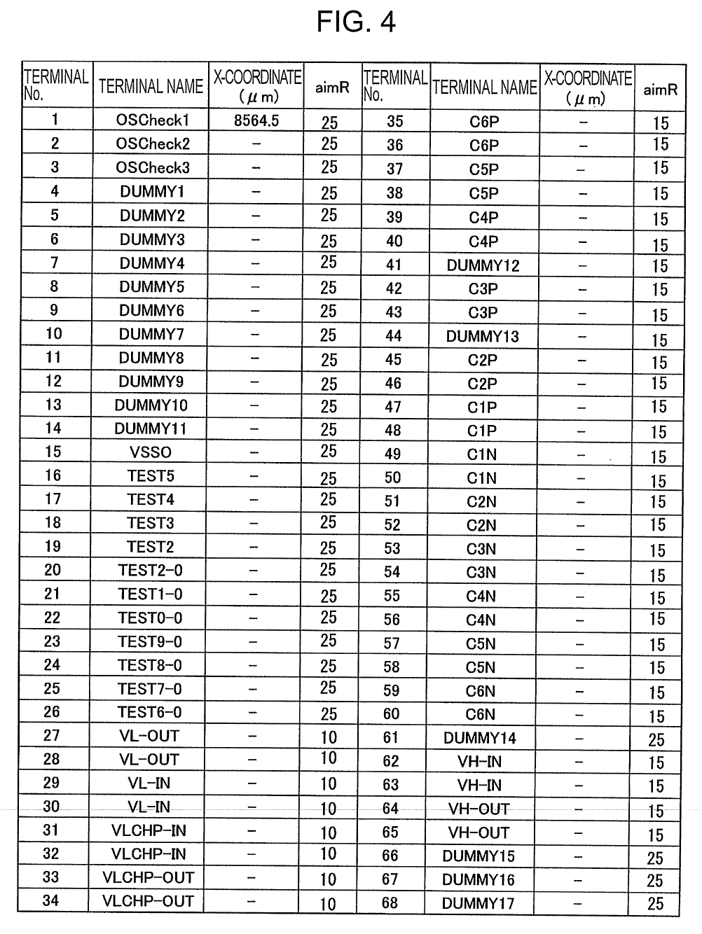

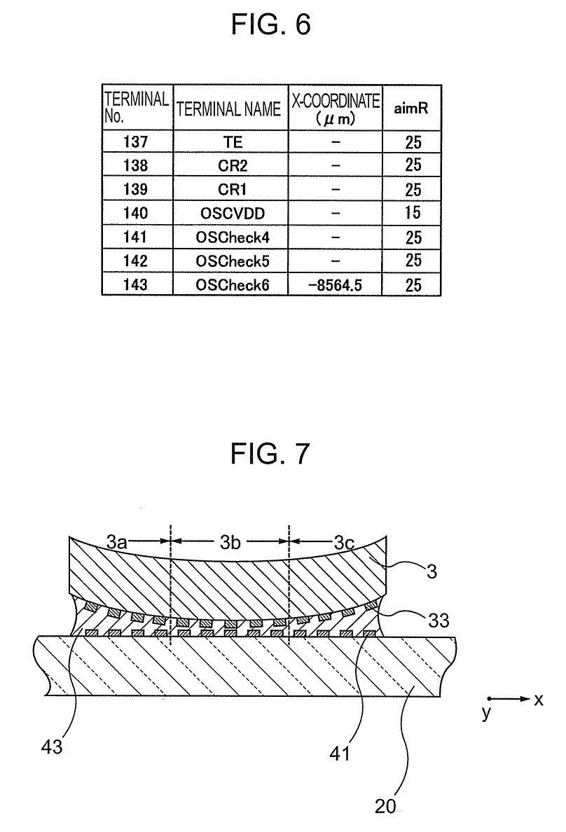

FIG. 3 is a diagram schematically illustrating the relationship between the bumps of the driving IC 3 and the terminals connected to the bumps. FIGS. 4 to 6 show names of the input terminals 41 electrically connected to the input bumps of the driving IC 3, positions of the input bumps of the driving IC 3 connected to the input terminals 41, and maximum allowable connection resistance values required for connecting the input bumps to the input terminals 41. The positions of the input bumps shown in FIGS. 4 to 6 are indicated by x-coordinate values (unit: μm) when x, y coordinates of the center of the driving IC 3 shown in FIG. 3 are (0, 0). In addition, the x and y directions shown in FIG. 2 correspond to the x and y directions shown in FIG. 4, and the longitudinal direction of the driving IC 3 corresponds to the x direction. In FIGS. 4 and 6, ‘aimR’ indicates a target connection resistance value of the bump and the terminal, and the driving IC 3 is preferably provided such that the connection resistance value is smaller than the target connection resistance value, from the viewpoint of operational characteristics. That is, ‘aimR’ is the maximum allowable value when a mass product margin of the connection resistance is considered.

As shown in FIG. 3, the driving IC 3 has a width ‘a’ of 1950 μm and a length ‘b’ of 17500 μm. A plurality of input bumps 33 (in this embodiment, 143 input bumps) are provided substantially in a line on one side of a bump surface 3a of the driving IC 3, and a plurality of output bumps 34 (in this embodiment, n+m output bumps) are provided substantially in a line on the other side of the bump surface 3a. Each input bump 33 has a size of about 70 μm by 70 μm, and the x-coordinate values shown in FIGS. 4 to 6 are x-coordinate values of the centers of the input bumps 33. The input bumps 33 are electrically connected to the input terminals 41 (which correspond to terminal Nos. 1 to 143 in FIG. 3) provided on the liquid crystal panel 4 through the ACF. The output bumps 34 are electrically connected to the segment electrode output terminals 25 (which correspond to ‘SEG1’ to ‘SEGn’ shown in FIG. 3) or the common electrode output terminals 24 (which correspond to ‘COM1’ to ‘COMm’ shown in FIG. 3) that are provided on the liquid crystal panel 4.

In FIGS. 4 to 6, terminal names ‘OS check’ corresponding to terminal Nos. 1 to 3 indicate input-side open check terminals. Terminal names ‘DUMMY’ corresponding to terminal Nos. 4 to 14 indicate dummy pads. A terminal name ‘VSSO’ corresponding to a terminal No. 15 indicates a terminal processing VSS level output terminal. Terminal names ‘TEST’ corresponding to terminal Nos. 16 to 19 indicate testing input terminals. Terminal names ‘TEST O’ corresponding to terminal Nos. 20 to 26 indicate testing output terminals. Terminal names ‘VL OUT’ corresponding to terminal Nos. 27 and 28 indicate liquid crystal driving voltage output terminals (common electrode ON level) serving as power supply terminals, and the value of ‘aimR’ is set to 10Ω. Terminal names ‘VL IN’ corresponding to terminal Nos. 29 and 30 indicate liquid crystal driving voltage input terminals (common electrode ON level) serving as power supply terminals, and the value of ‘aimR’ is set to 10Ω. The terminal Nos. 29 and 30 are electrically connected to the terminal Nos. 27 and 28, respectively. Terminal names ‘VLCHP IN’ corresponding to terminal Nos. 31 and 32 indicate input terminals of a step-up voltage 1, serving as power supply control terminals, and the value of ‘aimR’ is set to 10Ω. Terminal names ‘VLCHP OUT’ corresponding to terminal Nos. 33 and 34 indicate output terminals of a step-up voltage 1, serving as power supply control terminals, and the value of ‘aimR’ is set to 10Ω. The terminal Nos. 33 and 34 are electrically connected to the terminal Nos. 31 and 32, respectively. Terminal names ‘C6P to C4P’ corresponding to terminal Nos. 35 to 40 indicate step-up capacitor connecting terminals. A terminal name ‘DUMMY’ corresponding to a terminal No. 41 indicates a dummy pad. Terminal names ‘C3P’ corresponding to terminal Nos. 42 and 43 indicate step-up capacitor connecting terminals. A terminal name ‘DUMMY’ corresponding to a terminal No. 44 indicates a dummy pad. Terminal names ‘CP2 and CP1’ corresponding to terminal Nos. 45 and 48 indicate step-up capacitor connecting terminals. Terminal names ‘C1N to C6N’ corresponding to terminal Nos. 49 to 60 indicate step-up capacitor connecting terminals. A terminal name ‘DUMMY’ corresponding to a terminal No. 61 indicates a dummy pad. Terminal names ‘VH IN’ corresponding to terminal Nos. 62 and 63 indicate liquid crystal driving voltage input terminals (common electrode ON level) serving as power supply terminals, and the value of ‘aimR’ is set to 15Ω. Terminal names ‘VH OUT’ corresponding to terminal Nos. 64 and 65 indicate liquid crystal driving voltage output terminals (common electrode ON level) serving as power supply terminals, and the value of ‘aimR’ is set to 15Ω. The terminal Nos. 64 and 65 are electrically connected to the terminal Nos. 62 and 63, respectively. Terminal names ‘DUMMY’ corresponding to terminal Nos. 66 to 69 indicate dummy pads. Terminal names ‘CN’ corresponding to terminal Nos. 70 and 71 indicate step-up capacitor connecting terminals. Terminal names ‘DUMMY’ corresponding to terminal Nos. 72 and 73 indicate dummy pads. Terminal names ‘CP’ corresponding to terminal Nos. 74 and 75 indicate step-up capacitor connecting terminals. Terminal names ‘VDDHX2 IN’ corresponding to terminal Nos. 76 and 77 indicate input terminals of a step-up voltage 2, serving as power supply control terminals, and the value of ‘aimR’ is set to 10Ω. Terminal names ‘VDDHX2 OUT’ corresponding to terminal Nos. 78 and 79 indicate output terminals of the step-up voltage 2, serving as power supply control terminals, and the value of ‘aimR’ is set to 10Ω. The terminal Nos. 76 and 77 are electrically connected to the terminal Nos. 78 and 79, respectively. Terminal names ‘COP’ corresponding to terminal Nos. 80 and 81 have ‘aimR’ of 15Ω. Terminal names ‘CON’ corresponding to terminal Nos. 82 and 83 have ‘aimR’ of 15Ω. Terminal names ‘VDDH’ corresponding to terminal Nos. 84 and 85 indicate analog power source terminals serving as power supply terminals, and the value of ‘aimR’ is set to 5Ω. Terminal names ‘VDDH2’ corresponding to terminal Nos. 86 and 87 indicate voltage boosting power source terminals serving as power supply terminals, and the value of ‘aimR’ is set to 5Ω. Terminal names ‘GNDH3’ corresponding to terminal Nos. 88 to 90 indicate voltage boosting ground terminals serving as ground terminals, and the value of ‘aimR’ is set to 5Ω. Terminal names ‘GNDH2’ corresponding to terminal Nos. 91 to 93 indicate analog ground terminals serving as ground terminals, and the value of ‘aimR’ is set to 5Ω. Terminal names ‘GNDL’ corresponding to terminal Nos. 94 to 96 indicate MPU-interface internal logic ground terminals serving as ground terminals, and the value of ‘aimR’ is set to 5Ω. Terminal names ‘VDD’ corresponding to terminal Nos. 97 to 99 indicate MPU-interface internal logic power source terminals serving as power supply terminals, and the value of ‘aimR’ is set to 5Ω. Terminal names ‘VDCT’ corresponding to terminal Nos. 100 to 101 indicate polarity-inverting reference voltage output terminals. Terminal names ‘VD OUT’ corresponding to terminal Nos. 102 and 103 indicate liquid crystal driving voltage output terminals (common electrode OFF level and segment electrode ON level) serving as power supply terminals, and the value of ‘aimR’ is set to 5Ω. Terminal names ‘VD IN’ corresponding to terminal Nos. 104 and 105 indicate liquid crystal driving voltage input terminals (common electrode OFF level and segment electrode ON level) serving as power supply terminals, and the value of ‘aimR’ is set to 10Ω. The terminal Nos. 102 and 103 are electrically connected to the terminal Nos. 104 and 105, respectively. A terminal name ‘A0’ corresponding to a terminal No. 106 indicates a command/data discrimination signal terminal. A terminal name ‘XRD’ corresponding to a terminal No. 107 indicates an inversion read signal terminal. A terminal name ‘XWR’ corresponding to a terminal No. 108 indicates a signal terminal. A terminal name ‘XCS’ corresponding to a terminal No. 109 indicates an MPU-interface chip selector terminal. A terminal name ‘XRES’ corresponding to a terminal No. 110 indicates a reset input terminal. Terminal names ‘D0 to D1’ corresponding to terminal Nos. 111 and 118 indicate MPU-interface data terminals. A terminal name ‘BCK’ corresponding to a terminal No. 119 indicates an EEPROM I/F clock terminal. A terminal name ‘BDATA’ corresponding to a terminal No. 120 indicates an EEPROM I/F data terminal. A terminal name ‘BRST’ corresponding to a terminal No. 121 indicates an EEPROM I/F chip selector terminal. A terminal name ‘VSSO’ corresponding to a terminal No. 122 indicates a terminal-processing VSS level output terminal serving as a power supply terminal, and the value of ‘aimR’ is set to 15Ω. A terminal name ‘OSC1’ corresponding to a terminal No. 123 indicates an external clock input terminal. A terminal name ‘VDDO’ corresponding to a terminal No. 124 indicates a terminal-processing VDD level output terminal serving as a power supply terminal, and the value of ‘aimR’ is set to 15Ω. A terminal name ‘OSSEL’ corresponding to a terminal No. 125 indicates a terminal for performing the switching between an integrated OSC clock for display and an external input clock. A terminal name ‘VSSO’ corresponding to a terminal No. 126 indicates a terminal-processing VSS level output terminal serving as a power supply terminal, and the value of ‘aimR’ is set to 15Ω. A terminal name ‘INISEL’ corresponding to a terminal No. 127 indicates a terminal for setting the connection of an EEPROM. A terminal name ‘VDDO’ corresponding to a terminal No. 128 indicates a terminal-processing VDD level output terminal serving as a power supply terminal, and the value of ‘aimR’ is set to 15Ω. A terminal name ‘RESSEL’ corresponding to a terminal No. 129 indicates a terminal for setting an automatic OFF sequence operation after resetting is released. A terminal name ‘VSSO’ corresponding to a terminal No. 130 indicates a terminal-processing VSS level output terminal serving as a power supply terminal, and the value of ‘aimR’ is set to 15Ω. A terminal name ‘PSB’ corresponding to a terminal No. 131 indicates an interface mode switching terminal. A terminal name ‘VDDO’ corresponding to a terminal No. 132 indicates a terminal-processing VDD level output terminal serving as a power supply terminal, and the value of ‘aimR’ is set to 15Ω. A terminal name ‘C86’ corresponding to a terminal No. 133 indicates an interface switching terminal. A terminal name ‘VSSO’ corresponding to a terminal No. 134 indicates a terminal-processing VSS level output terminal serving as a power supply terminal, and the value of ‘aimR’ is set to 15Ω. Terminal names ‘TEST’ corresponding to terminal Nos. 135 and 136 indicate testing input terminals. A terminal name ‘TE’ corresponding to a terminal No. 137 indicates a tearning effect output terminal. A terminal name ‘CR2’ corresponding to a terminal No. 138 indicates an input terminal for connecting a resistor for a low-frequency transmitting circuit. A terminal name ‘CR1’ corresponding to a terminal No. 139 indicates an output terminal for connecting a resistor for a low-frequency transmitting circuit. A terminal name ‘OSCVDD’ corresponding to a terminal No. 140 indicates a power source terminal for a transmitting circuit, serving as a power supply terminal, and the value of ‘aimR’ is set to 15Ω. Terminal names ‘OS check’ corresponding to terminal Nos. 141 to 143 indicate output-side open/shut check terminals. Although a detailed description will be made later, in this embodiment, the value of ‘aimR’ is low, and at least one of the power supply terminal, the power supply control terminal, and the ground terminal is arranged substantially at the center of the driving IC 3 in the longitudinal direction thereof. That is, a terminal connected to the input pad 33 that is positioned substantially at the center of the driving IC 3 has an allowable connection resistance value smaller than that of other terminals. It is preferable that the terminals having a target resistance value of 5 to 15Ω, more preferably, a target resistance value of 5 to 10Ω, be arranged at the center of the driving IC 3.

The power supply circuit 100 includes a voltage boosting circuit and a potential adjusting circuit to generate a driving voltage required for a liquid crystal display. In this embodiment, a charge pump method is used for the voltage boosting circuit. In addition, the potential adjusting circuit has an operational amplifier and a voltage adjusting resistor.

As described above, in this embodiment, the power supply terminals, the power supply control terminals, and the ground terminals required to have a low connection resistance value aimR are provided as terminals connected to the input bumps 33 that are positioned substantially at the center (which corresponds to the terminal Nos. 49 to 105 in this embodiment) of the driving IC 3, among the input bumps 33 provided in the longitudinal direction (the x direction) of the driving IC 3. In this way, even when the ACF becomes loose between the input bumps 33 and the input terminals 41 over time, the connection resistance between the input bumps 33 and the input terminals 41 is not increased at the center of the driving IC 3, and thus it is possible to achieve the liquid crystal device 1 having stable operational characteristics. That is, as shown in FIG. 7, when the driving IC 3 is mounted on the first glass substrate 20 by thermal pressing, the driving IC 3 is mounted on the first glass substrate 20 in a warped state due to a difference in thermal expansion coefficient between the first glass substrate 20 and the driving IC 3. Then, the ACF 43 at an outer side 3C of the driving IC 3 in the longitudinal direction (the x direction) thereof is loosened over time, which causes high connection resistance between the input bumps 33 and the input terminals 41 at the outer side 3c of the driving IC 3. Therefore, in this embodiment, terminals having a high aimR value of 50Ω are provided as the input terminals 41 electrically connected to the input bumps 33 at the outer side 3c of the driving IC 3 where the connection resistance value may be increased due to the loosened ACF 43 over time, and terminals having a low aimR value of 5Ω are provided as the input terminals 41 electrically connected to the input bumps 33 at a central portion 3b of the driving IC 3. In this way, even when the ACF 43 is loosened over time causing high connection resistance between the input bumps 33 and the input terminals 41 corresponding thereto at the outer side 3c of the driving IC 3, display characteristics of the liquid crystal device are not deteriorated since the input terminals 41 having a maximum allowable connection resistance value are arranged at the outer side 3c of the driving IC 3. In addition, the ACF 43 is negligibly loosened at the central portion 3b of the driving IC 3 over time, and the connection resistance between the input bumps 33 and the input terminals 41 corresponding thereto is negligibly changed at the central portion 3b of the driving IC 3. Therefore, at least one of the power supply terminal, the power supply control terminal, and the ground terminal which have the maximum allowable connection resistance value is provided in a region corresponding to the central portion 3b of the driving IC 3 where the change of the connection resistance is small, which makes it possible to prevent the deterioration of display characteristics of a liquid crystal device over time.

### Second Embodiment

In the first embodiment, a charge pump method is used for the voltage boosting circuit. However, in this embodiment, a driving IC, serving as a semiconductor device, will be described when a chopper method is used for the voltage boosting circuit. In addition, in the first embodiment, the driving IC 3 includes the power supply circuit, the common electrode driver, and the segment electrode driver. However, in this embodiment, a driving IC 103 includes a power supply circuit and a common electrode driver.

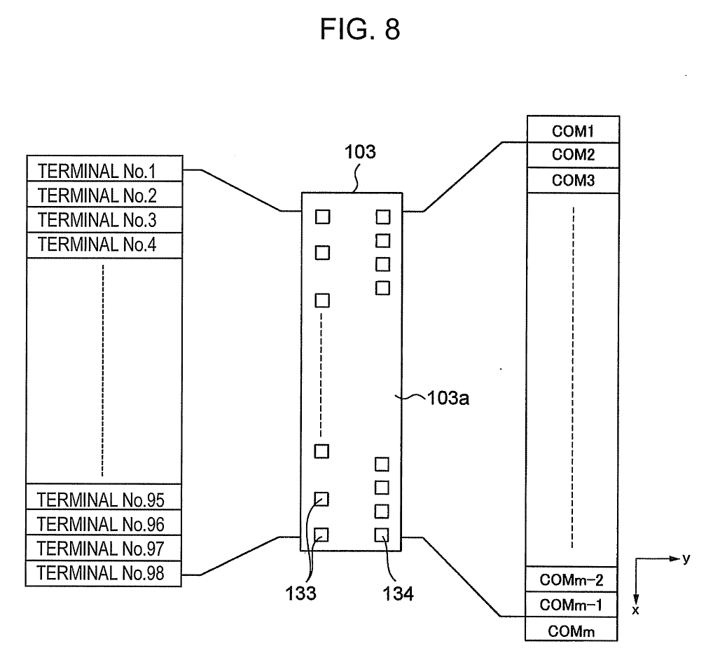

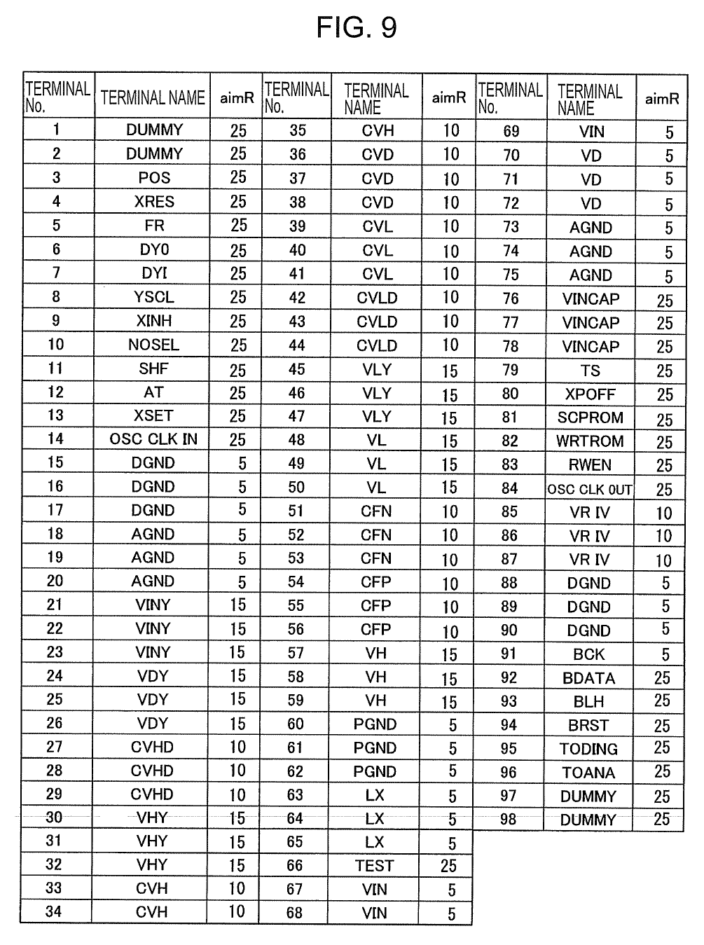

The driving IC 103 of this embodiment will be described with reference to FIGS. 8 and 9.

FIG. 8 is a diagram schematically illustrating the relationship between bumps of the driving IC 103 and terminals connected thereto. FIG. 9 shows names of the input terminals electrically connected to the input bumps of the driving IC 103 and allowable connection resistance values required for connection between the input bumps and the input terminals. In FIG. 9, ‘aimR’ indicates a target connection resistance value of the input bump and the input terminal, and the driving IC 103 is preferably provided such that the connection resistance value is smaller than those of the target connection resistance value, from the viewpoint of operational characteristics of a liquid crystal device. That is, ‘aimR’ is a maximum allowable connection resistance value.

As shown in FIG. 8, a plurality of input bumps 133 (in this embodiment, 98 input bumps) are provided substantially in a line on one side of a bump surface 103a of the driving IC 103, and a plurality of output bumps 134 (in this embodiment, m output bumps) are provided substantially in a line on the other side of the bump surface 103a. The input bumps 133 are electrically connected to input terminals (which correspond to terminal Nos. 1 to 98 in FIG. 8) provided on a liquid crystal panel through an ACF. The output bumps 134 are electrically connected to common electrode output terminals 24 (which correspond to ‘COM1’ to ‘COMm’ shown in FIG. 8) that are provided on the liquid crystal panel.

In FIG. 9, terminal names ‘DUMMY’ corresponding to terminal Nos. 1 and 2 indicate dummy pads. A terminal name ‘POS’ corresponding to a terminal No. 3 indicates a signal terminal. A terminal name ‘XRES’ corresponding to a terminal No. 4 indicates a signal terminal. A terminal name ‘FR’ corresponding to a terminal No. 5 indicates a signal terminal. A terminal name ‘DY0’ corresponding to a terminal No. 6 indicates a signal terminal. A terminal name ‘DY2’ corresponding to a terminal No. 7 indicates a signal terminal. A terminal name ‘YSCL’ corresponding to a terminal No. 8 indicates a signal terminal. A terminal name ‘XINH’ corresponding to a terminal No. 9 indicates a signal terminal. A terminal name ‘NOSEL’ corresponding to a terminal No. 10 indicates a signal terminal. A terminal name ‘SHF’ corresponding to a terminal No. 11 indicates a signal terminal. A terminal name ‘ALT’ corresponding to a terminal No. 12 indicates a signal terminal. A terminal name ‘XSET’ corresponding to a terminal No. 13 indicates a signal terminal. A terminal name ‘OSC CLK IN’ corresponding to a terminal No. 14 indicates a signal terminal. Terminal names ‘DGND’ corresponding to terminal Nos. 15 to 17 indicate digital signal ground terminals. Terminal names ‘AGND’ corresponding to terminal Nos. 18 to 20 indicate analog signal ground terminals having an ‘aimR’ of 5Ω. Terminal names ‘VINY’ corresponding to terminal Nos. 21 to 23 indicate input power source terminals, serving as power source terminals, having an ‘aimR’ of 15Ω. Terminal names ‘VDY’ corresponding to terminal Nos. 24 to 26 indicate VD input terminals of the common electrode driver, and the aimR thereof is 5Ω. Terminal names ‘CVHD’ corresponding to terminal Nos. 27 to 29 indicate output terminals of a charge pump voltage (VH−VD) of the common electrode driver. Terminal names ‘VHY’ corresponding to terminal Nos. 30 to 32 indicate VH input terminals of the common electrode driver, serving as power source terminals, and the aimR thereof is 15Ω. Terminal names ‘CVH’ corresponding to terminal Nos. 33 to 35 indicate flying capacitor connection terminals for a (VH−VD) voltage of a C/P circuit of the common electrode driver. Terminal names ‘CVD’ corresponding to terminal Nos. 36 to 38 indicate flying capacitor connection terminals for (VH−VD), (VL+VD) voltages of the C/P circuit of the common electrode driver. Terminal names ‘CVL’ corresponding to terminal Nos. 39 to 41 indicate flying capacitor connection terminals for the (VL+VD) voltage of the C/P circuit of the common electrode driver. Terminal names ‘CVLD’ corresponding to terminal Nos. 42 to 44 indicate output terminals of a charge pump voltage (VL+VD) of the common electrode driver. Terminal names ‘VLY’ corresponding to terminal Nos. 45 to 47 indicate VL input terminals of the common electrode driver, serving as power source terminals, and the aimR thereof is 15Ω. Terminal names ‘VL’ corresponding to terminal Nos. 48 to 50 indicate VL output and voltage detection terminals. Terminal names ‘CFN’ corresponding to terminal Nos. 51 to 53 indicate capacitor connection terminals for a VL-based charge pump. Terminal names ‘CFP’ corresponding to terminal Nos. 54 to 56 indicate capacitor connection terminals for the VL-based charge pump. Terminal names ‘VH’ corresponding to terminal Nos. 57 to 59 indicate VH output and voltage detection terminals. Terminal names ‘PGND’ corresponding to terminal Nos. 60 to 62 indicate power ground terminals. Terminal names ‘LX’ corresponding to terminal Nos. 63 to 65 indicate VD/VH interface connection terminals. A terminal name ‘TEST’ corresponding to a terminal No. 66 indicates a signal terminal. Terminal names ‘VIN’ corresponding to terminal Nos. 67 to 69 indicate input power source terminals, and the aimR thereof is 5Ω. Terminal names ‘VD’ corresponding to terminal Nos. 70 to 72 indicate signal terminals. Terminal names ‘AGND’ corresponding to terminal Nos. 73 to 75 indicate analog ground terminals, and the aimR thereof is 5Ω. Terminal names ‘VINCAP’ corresponding to terminal Nos. 76 to 78 indicate capacitor connection terminals for a VIN filter. A terminal name ‘TS’ corresponding to a terminal No. 79 indicates a signal terminal. A terminal name ‘XPOFF’ corresponding to a terminal No. 80 indicates a signal terminal. A terminal name ‘SCPEN’ corresponding to a terminal No. 81 indicates a signal terminal. A terminal name ‘WRTROM’ corresponding to a terminal No. 82 indicates a signal terminal. A terminal name ‘RWEN’ corresponding to a terminal No. 83 indicates a signal terminal. A terminal name ‘OSC CLK OUT’ corresponding to a terminal No. 84 indicates a signal terminal. Terminal names ‘VROM’ corresponding to terminal Nos. 85 to 87 indicate signal terminals. Terminal names ‘DGND’ corresponding to terminal Nos. 88 to 90 indicate digital signal ground terminals. A terminal name ‘BCK’ corresponding to a terminal No. 91 indicates a signal terminal. A terminal name ‘BDATA’ corresponding to a terminal No. 92 indicates a signal terminal. A terminal name ‘BLH’ corresponding to a terminal No. 93 indicates a signal terminal. A terminal name ‘BRST’ corresponding to a terminal No. 94 indicates a signal terminal. A terminal name ‘TODIG’ corresponding to a terminal No. 95 indicates a signal terminal. A terminal name ‘TOANA’ corresponding to a terminal No. 96 indicates a signal terminal. Terminal names ‘DUMMY’ corresponding to terminal Nos. 97 and 98 indicate dummy pads. The terminals having an aimR of 5 to 15Ω are provided at the center of the driving IC 103.

In this embodiment, the power supply terminals, the power supply control terminals, and the ground terminals required to have a low connection resistance value aimR are provided as terminals connected to the input bumps 133 that are positioned substantially at the center (which corresponds to the terminal Nos. 30 to 70 in this embodiment) of the driving IC 103, among the input bumps 133 provided in the longitudinal direction (the x direction) of the driving IC 103. In this way, even when the ACF becomes loose between the input bumps 133 and the input terminals over time, the connection resistance between the input bumps 133 and the input terminals is not increased at the center of the driving IC 103, and thus it is possible to achieve a liquid crystal device having stable operational characteristics.

### Third Embodiment

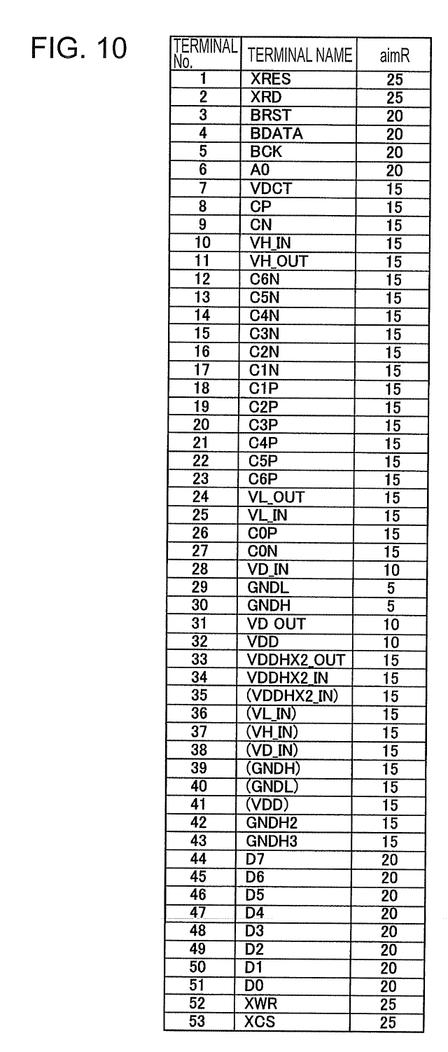

Next, a modification of the driving IC will be described. FIG. 10 is an explanatory diagram illustrating terminals connected to bumps of a driving IC according to a third embodiment.

In this embodiment, a plurality of input bumps of the driving IC is arranged such that the maximum allowable connection resistance value between input bumps and input terminals decreases from the inside toward the outside in the x direction. More specifically, a terminal No. 1 having a terminal name ‘XRES’ has an aimR of 25Ω, and a terminal No. 2 having a terminal name ‘XRD’ has an aimR of 25Ω. A terminal No. 3 having a terminal name ‘BRST’ has an aimR of 20Ω, and a terminal No. 4 having a terminal name ‘BDATA’ has an aimR of 20Ω. A terminal No. 5 having a terminal name ‘BCK’ has an aimR of 20Ω, and a terminal No. 6 having a terminal name ‘A0’ has an aimR of 20Ω. A terminal No. 7 having a terminal name ‘VDCT’ has an aimR of 15Ω, and a terminal No. 8 having a terminal name ‘CP’ has an aimR of 15Ω. A terminal No. 9 having a terminal name ‘CN’ has an aimR of 15Ω, and a terminal No. 10 having a terminal name ‘VH_IN’ has an aimR of 15Ω. A terminal No. 11 having a terminal name ‘VH_OUT’ has an aimR of 15Ω, and a terminal No. 12 having a terminal name ‘C6N’ has an aimR of 15Ω. A terminal No. 13 having a terminal name ‘C5N’ has an aimR of 15Ω, and a terminal No. 14 having a terminal name ‘C4N’ has an aimR of 15Ω. A terminal No. 15 having a terminal name ‘C3N’ has an aimR of 15Ω, and a terminal No. 16 having a terminal name ‘C2N’ has an aimR of 15Ω. A terminal No. 17 having a terminal name ‘C1N’ has an aimR of 15Ω, and a terminal No. 18 having a terminal name ‘C1P’ has an aimR of 15Ω. A terminal No. 19 having a terminal name ‘C2P’ has an aimR of 15Ω, and a terminal No. 20 having a terminal name ‘C3P’ has an aimR of 15Ω. A terminal No. 21 having a terminal name ‘C4P’ has an aimR of 15Ω, and a terminal No. 22 having a terminal name ‘C5P’ has an aimR of 15Ω. A terminal No. 23 having a terminal name ‘C6P’ has an aimR of 15Ω, and a terminal No. 24 having a terminal name ‘VL_OUT’ has an aimR of 15Ω. A terminal No. 25 having a terminal name ‘VL_IN’ has an aimR of 15Ω, and a terminal No. 26 having a terminal name ‘C0P’ has an aimR of 15Ω. A terminal No. 27 having a terminal name ‘CON’ has an aimR of 15Ω, and a terminal No. 28 having a terminal name ‘VD_IN’ has an aimR of 10Ω. A terminal No. 29 having a terminal name ‘GNDL’ has an aimR of 5Ω, and a terminal No. 30 having a terminal name ‘GNDH’ has an aimR of 5Ω. A terminal No. 31 having a terminal name ‘VD_OUT’ has an aimR of 10Ω, and a terminal No. 32 having a terminal name ‘VDD’ has an aimR of 10Ω. A terminal No. 33 having a terminal name ‘VDDHX2_OUT’ has an aimR of 15Ω, and a terminal No. 34 having a terminal name ‘VDDHX2_IN’ has an aimR of 15Ω. A terminal No. 35 having a terminal name ‘VDDHX2_IN’ has an aimR of 15Ω, and a terminal No. 36 having a terminal name ‘VL_IN’ has an aimR of 15Ω. A terminal No. 37 having a terminal name ‘VH_IN’ has an aimR of 15Ω, and a terminal No. 38 having a terminal name ‘VD_IN’ has an aimR of 15Ω. A terminal No. 39 having a terminal name ‘GNDH’ has an aimR of 15Ω, and a terminal No. 40 having a terminal name ‘GNDL’ has an aimR of 15Ω. A terminal No. 41 having a terminal name ‘VDD’ has an aimR of 15Ω, and a terminal No. 42 having a terminal name ‘GNDH2’ has an aimR of 15Ω. A terminal No. 43 having a terminal name ‘GNDH3’ has an aimR of 15Ω, and a terminal No. 44 having a terminal name ‘D7’ has an aimR of 20Ω. A terminal No. 45 having a terminal name ‘D6’ has an aimR of 20Ω, and a terminal No. 46 having a terminal name ‘D5’ has an aimR of 20Ω. A terminal No. 47 having a terminal name ‘D4’ has an aimR of 20Ω, and a terminal No. 48 having a terminal name ‘D3’ has an aimR of 20Ω. A terminal No. 49 having a terminal name ‘D2’ has an aimR of 20Ω, and a terminal No. 50 having a terminal name ‘D1’ has an aimR of 20Ω. A terminal No. 51 having a terminal name ‘D0’ has an aimR of 20Ω, and a terminal No. 52 having a terminal name ‘XWR’ has an aimR of 25Ω. A terminal No. 53 having a terminal name ‘XCS’ has an aimR of 25Ω.

In this embodiment, the power supply terminals, the power supply control terminals, and the ground terminals required to have a low connection resistance value aimR are provided as terminals connected to the input bumps that are positioned substantially at the center of the driving IC, among the input bumps provided in the longitudinal direction (the x direction) of the driving IC. In this way, even when the ACF becomes loose between the input bumps and the input terminals over time, the connection resistance between the input bumps and the input terminals is not increased at the center of the driving IC, and thus it is possible to achieve a liquid crystal device having stable operational characteristics.

### Electronic Apparatus

Next, an electronic apparatus including the liquid crystal device 1 will be described.

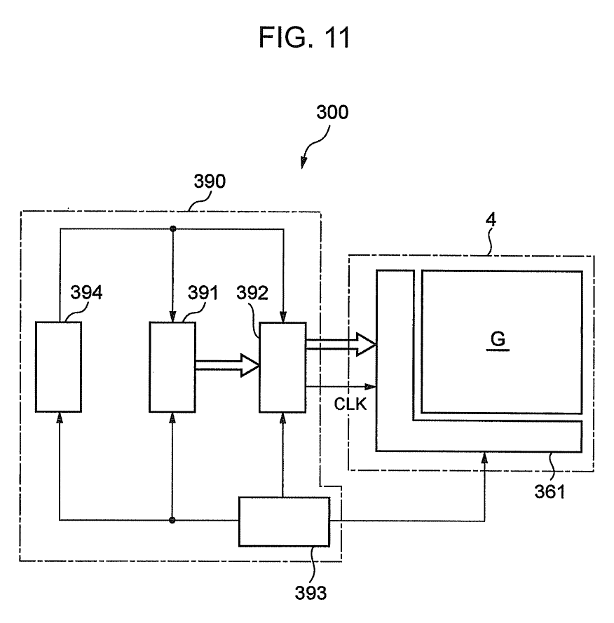

FIG. 11 is a diagram schematically illustrating the overall structure of a display control system of an electronic apparatus according to the invention.

An electronic apparatus 300 includes, for example, a liquid crystal panel 4 and a display control circuit 390 shown in FIG. 11 as a display control system. The display control circuit 390 has a display information output source 391, a display information processing circuit 392, a power supply circuit 393, and a timing generator 394.

Further, the liquid crystal panel 10 has a driving circuit 361 for driving a display region G thereon. The driving circuit 361 corresponds to the driving IC 3 or 103 of the liquid crystal device 1.

The display information output source 391 includes a memory composed of, for example, a ROM (read only memory) or a RAM (random access memory), a storage unit composed of, for example, a magnetic recording disk or an optical recording disk, and a tuning circuit for tuning and outputting digital image signals. The display information output source 391 supplies display information to the display information processing circuit 392 in the form of image signals having a predetermined format, on the basis of various clock signals generated by the timing generator 394.

Further, the display information processing circuit 392 includes various well-known circuits, such as a serial-to-parallel conversion circuit, an amplifying/inverting circuit, a rotation circuit, a gamma correction circuit, and a clamp circuit, and processes the input display information to supply the image information thereof to the driving circuit 361 together with a clock signal CLK. The driving circuit 361 includes a scanning line driving circuit, a data line driving circuit, and a test circuit. In addition, the power supply circuit 393 applies a predetermined voltage to the above-mentioned components.

The electronic apparatus 300 has stable display characteristics since the connection resistance between the input bumps and the input terminals does not vary over time in the driving ICs 3 and 103.

The electronic apparatus includes, as concrete examples, a cellular phone, a personal computer, a touch panel equipped with a liquid crystal device, a projector, a liquid crystal television, a viewfinder-type and monitor-direct-view-type videotape recorder, a car navigation system, a pager, an electronic organizer, an electronic calculator, a word processor, a workstation, a television phone, and a POS terminal. Of course, the above-mentioned liquid crystal device 1 can be applied to these electronic apparatuses as display units.

Further, the electro-optical device and the electronic apparatus of the invention are not limited to the above-described embodiments, and various modifications and changes thereof can be made without departing from the scope and spirit of the invention.

For example, in the above-described embodiments, the liquid crystal device using TFD elements is used, but a simple matrix liquid crystal device or a liquid crystal device using TFT elements can be used. In addition, in the above-described embodiments, the liquid crystal device is used as an electro-optical device, but an organic electro-luminescent device adopting a COG manner can be used.

What is claimed is:

1. A method comprising:
determining a plurality of signals to be exchanged between a substrate and a semiconductor device electrically connected to the substrate through a conductive member;
determining a sensitivity to increased connection resistance for each of the plurality of signals;
arranging the plurality of signals on the conductive member by grouping the plurality of signals into first, second, and third sets, wherein the second set of input terminals is located laterally from the first set of input terminals in a first direction, and wherein the third set of input terminals is arranged laterally from the second set of input terminals in the first direction; and
assigning ones of the plurality of signals having the highest sensitivities to the second set, and assigning others of the plurality of signals to the first and third sets.

2. The method of claim 1 wherein the plurality of signals includes analog power supply signals and analog ground signals, and further comprising assigning the analog power supply signals and analog ground signals to the second set.

3. The method of claim 1 wherein the first, second, and third sets are arranged generally collinearly.

4. The method of claim 1 wherein the plurality of signals includes dummy signals, and further comprising assigning the dummy signals to the first and third sets.

5. The method of claim 1 wherein the conductive member is a conductive organic member.
